(19) United States
(12) Patent Application Publication
(10) Pub. No.: US 2020/0301053 A1
(43) Pub. Date: Sep. 24, 2020

(54) OPTICAL SENSING DEVICE EMPLOYING LIGHT INTENSITY DETECTORS INTEGRATED WITH NANOSTRUCTURES

(71) Applicant: Coherent AI LLC, Redwood City, CA (US)

(72) Inventors: Xingze Wang, Durham, NC (US); Xin Lei, San Carlos, CA (US); Yibo Zhu, Redwood City, CA (US)

(73) Assignee: Coherent AI LLC, Redwood City, CA (US)

(21) Appl. No.: 16/359,875

(22) Filed: Mar. 20, 2019

(51) Int. Cl. G02B 5/28; G01J 1/44; G01J 1/02; G01J 1/04; H01L 27/144

(52) U.S. Cl. CPC G02B 5/288; G01J 1/44; G01J 1/0209; G01J 1/0488; G02B 2207/101; H01L 27/1443; H01L 27/1446; G01J 2001/448; G01J 1/0411

(57) ABSTRACT

Optical sensing devices employing light intensity detectors integrated with nanostructures. In some embodiments, the nanostructures are 3D nanostructures having feature sizes in all three dimensions comparable to a wavelength range of the incident light, and are used for hyperspectral sensing. In some other embodiments, the nanostructures are simultaneous sensitive to both the spectrum and one or more of polarization, angle and phase information of the incident light field, to provide multi-modal optical sensing devices. In some other embodiments, each spatial pixel of an image sensor includes a group of sampling pixels configured for hyperspectral sensing and another group of sampling pixels configured for sensing polarization, angle or phase of the incident light.

### BACKGROUND OF THE INVENTION

### Field of the Invention

This invention relates to optical sensing devices, and in particular, it relates to optical sensing devices based on light intensity detectors integrated with nanostructures.

### Description of Related Art

Spectrometers using an integrated frequency filter and light sensor structure have been described. For example, U.S. Pat. Appl. Pub. No. 20150211922, Jul. 30, 2015, describes a spectrometer which “employs multiple filters having complex filter spectra that can be generated robustly from received light over short optical path lengths. The complex filter spectra provide data that can be converted to a spectrum of the received light using compressed sensing techniques.” (Id., Abstract). More specifically, the spectrometer includes “a frequency filter receiving light and modifying the light according to a set of different filter spectra each defining a frequency-dependent attenuation of the received light to provide a corresponding set of filtered light beams each associated with a different filter spectra; a broadband light detector receiving the set of filtered light beams to provide a corresponding set of independent measures of each filtered light beam; an electronic computer executing a program stored in non-transient memory to receive the independent measures of the filtered light beams to generate a spectrum derived from the set of independent measures, the spectrum indicating intensity as a function of frequency for different light frequencies over a range of frequencies; wherein each different filter spectra is a broadband spectrum with substantially non-periodic variations in value as a function of frequency.” (Id., claim 1.) It also describes a method of measuring a spectrum using such a spectrometer, which includes “(a) illuminating a sample material to obtain multiple independent measures of each filtered light beam; (b) comparing the multiple independent measures of each light signal to known different filter spectra to produce partial spectra indicating selective frequency attenuation of a broadband light signal by the filter spectra and the sample material; and (c) combining the partial spectra into the spectrum.” (Id., claim 15.)

U.S. Pat. Appl. Pub. No. 20140146207, May 29, 2014, describes a “solid-state image sensor and an imaging system which are capable of providing a solid-state image sensor and an imaging system which are capable of realizing a spectroscopic/imaging device for visible/near-infrared light having a high sensitivity and high wavelength resolution, and of achieving two-dimensional spectrum mapping with high spatial resolution. There are provided a two-dimensional pixel array, and a plurality of types of filters that are arranged facing a pixel region of the two-dimensional pixel array, the filters each including a spectrum function and a periodic fine pattern shorter than a wavelength to be detected, wherein each of the filters forms a unit which is larger than the photoelectric conversion device of each pixel on the two-dimensional pixel array, where one type of filter is arranged for a plurality of adjacent photoelectric conversion device groups, wherein the plurality of types of filters are arranged for adjacent unit groups to form a filter bank, and wherein the filter banks are arranged in a unit of N×M, where N and M are integers of one or more, facing the pixel region of the two-dimensional pixel array.” (Id., Abstract.)

WIPO Pub. No. WO2013064510 describes “A spectral camera for producing a spectral output [which] has an objective lens for producing an image, a mosaic of filters for passing different bands of the optical spectrum, and a sensor array arranged to detect pixels of the image at the different bands passed by the filters, wherein for each of the pixels, the sensor array has a cluster of sensor elements for detecting the different bands, and the mosaic has a corresponding cluster of filters of different bands, integrated on the sensor element so that the image can be detected simultaneously at the different bands. The filters are first order Fabry-Perot filters, which can give any desired passband to give high spectral definition.” (Id., Abstract.)

Z. Wang et al., Spectral analysis based on compressive sensing in nanophotonic structures, Optics Express, Vol. 22, No. 21, 25608-25614, 13 Oct. 2014 (“Wang et al. 2014”), describes a “method of spectral sensing based on compressive sensing . . . . The random bases used in compressive sensing are created by the optical response of a set of different nanophotonic structures, such as photonic crystal slabs. The complex interferences in these nanostructures offer diverse spectral features suitable for compressive sensing.” (Id., Abstract.)

### SUMMARY

The present invention is directed to an optical sensing device and related fabrication method that substantially obviates one or more of the problems due to limitations and disadvantages of the related art.

One object of the present invention is to provide improved sensors for high resolution hyperspectral imaging.

Another object of the present invention is to provide multi-modal optical sensing devices for simultaneous sensing spectral information and one or more of polarization, angle and phase information of the incident light field.

Additional features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve the above objects, the present invention provides an optical sensing device, which includes: a light intensity detector; and a three-dimensional nanostructure integrated above the light intensity detector, the three-dimensional nanostructure having feature sizes in all three dimensions comparable to a wavelength range of an incident light to be detected. In some embodiments, the three-dimensional nanostructure including a plurality of layers of two-dimensional nanostructures.

In another aspect, the present invention provides an optical sensing device, which includes: a plurality of light intensity detectors disposed adjacent to each other; and a plurality of nanostructures each integrated above a corresponding one of the plurality of light intensity detectors, wherein the nanostructures for different light intensity detectors have different feature sizes and locations, and wherein the nanostructure for each light intensity detector has an intrinsic anisotropy which includes either an anisotropy in geometries of the nanostructure or an anisotropy in a material that forms the nanostructure or both, and the nanostructures for different light intensity detectors have different intrinsic anisotropies.

In yet another aspect, the present invention provides an optical sensing device which includes: a plurality of light intensity detectors disposed adjacent to each other within an area; and a plurality of nanostructures each integrated above a corresponding one of the plurality of light intensity detectors, wherein light intensity detectors includes a first group of light intensity detectors located in a first region of the area and a second group of light intensity detectors located in a second region of the area, wherein the nanostructures for different ones of the second group of light intensity detectors are configured to have different spectral responses to an incident light and low sensitivities to an angle of the incident light, and the nanostructures for different ones of the first group of light intensity detectors are configured to have different responses to the angle of the incident light.

In yet another aspect, the present invention provides an optical sensing device which includes: a plurality of light intensity detectors disposed adjacent to each other; a plurality of nanostructures each integrated above a corresponding one of the plurality of light intensity detectors, wherein the plurality of light intensity detectors and corresponding nanostructures form an array of identical subunits, each subunit including an array of light intensity detectors and corresponding nanostructures, wherein within each subunit, the nanostructures for different light intensity detectors are different; a lenslet array disposed above the plurality of nanostructures, the lenslet array having a pitch larger than a pitch of the plurality of subunits in the array of subunits; and a transparent optical medium disposed in a space between the plurality of nanostructures and the lenslet array.

It is to be understood that both the foregoing general description and the following detailed description are exemplary and explanatory and are intended to provide further explanation of the invention as claimed.

### BRIEF DESCRIPTION OF THE DRAWINGS

FIGS. 1(a)-1(b) schematically illustrate a spectral sensor having a plurality of sampling pixels according to a first embodiment of the present invention.

FIG. 2 schematically illustrates a spectral sensor according to a second embodiment of the present invention.

FIGS. 3(a)-3(g) schematically illustrate two exemplary methods for manufacturing a 3D nanostructure for the spectral sensors of the first and second embodiments.

FIGS. 4(a)-4(c) schematically illustrate a spectral sensor having a plurality of sampling pixels according to a third embodiment of the present invention.

FIGS. 5(a)-5(c) schematically illustrate a spectral sensor having a plurality of sampling pixels according to a fourth embodiment of the present invention.

FIGS. 6(a)-6(h) schematically illustrate a method for manufacturing a 3D nanostructure for the spectral sensors of the fourth embodiment.

FIGS. 7(a)-7(b) schematically illustrate a spectral sensor having a plurality of sampling pixels according to a fifth embodiment of the present invention.

FIG. 8 schematically illustrates a method for manufacturing a 3D nanostructure for the spectral sensors of the fifth embodiment.

FIG. 9 schematically illustrates a spectral sensor having a plurality of sampling pixels according to a sixth embodiment of the present invention.

FIG. 10 schematically illustrates a method for manufacturing a 3D nanostructure for the spectral sensors of the sixth embodiment.

FIGS. 11(a)-11(c) schematically illustrate spectral sensors with bandpass sinters according to a seventh embodiment of the present invention.

FIGS. 12(a)-12(b) schematically illustrate a sensor for simultaneous hyperspectral and polarization sensing according to an eighth embodiment of the present invention.

FIG. 13 schematically illustrate a sensor for simultaneous hyperspectral and polarization sensing according to a ninth embodiment of the present invention.

FIGS. 14(a)-14(c) schematically illustrate a method for manufacturing a 3D nanostructure for the sensor of the ninth embodiment.

FIGS. 15(a)-15(d) schematically illustrate a sensor for simultaneous hyperspectral and incident angle sensing according to a tenth embodiment of the present invention.

FIG. 16 schematically illustrates a spatial pixel for simultaneous hyperspectral incident angle sensing according to an eleventh embodiment of the present invention.

### DETAILED DESCRIPTION OF PREFERRED EMBODIMENTS

Embodiments of the present invention provide optical sensing devices based on broadband light intensity detectors integrated with nanostructures, where the nanostructures, located above the light intensity detectors, have feature sizes in at least one dimension comparable to the wavelength of the incident light. Preferably, CMOS (complementary metal-oxide-semiconductor) image sensors are used as the light intensity detectors and are used in the descriptions below, but other image sensors such as CCD image sensors may be used as well.

In some embodiments, the optical sensing device is multi-modal, i.e., it has the capabilities of simultaneously detecting multiple parameters of the incident light field, including spectral, polarization, angle, and phase information.

In some embodiments, by extending the nanostructures into the direction (z direction) normal to the CMOS sensor surface (xy directions), the design space is greatly expanded. Variations of structural geometries in the two-dimensional plane parallel to the sensor surface are combined with that in the z direction to create more optical filters.

The nanostructures allow multiple scatterings and interferences of the light in the direction normal to the sensor surface (z direction) in addition to the direction parallel to the sensor surface (xy plane). This effectively increases the optical path length, encoding the light intensity to be detected with the light intensity detector with complex patterns that reveals more information of the incident light field.

To exploit the multiple scatterings and interferences of light from the nanostructures, the feature size of the nanostructures is preferably comparable to the representative wavelength of the incident light, and the range is preferably within 1/10 to 5 times of the representative wavelength. The nanostructures is preferably placed within 10 μm from the surface of the CMOS image sensor, and therefore the photocurrent of the CMOS image sensor records the optical response of the nanostructures.

To describe the structure of the optical sensing device, three levels of “pixels” are defined here: spatial pixels, sampling pixels, and detector pixels. A detector pixel is a single photocurrent generating unit, for example a photodiode, and its associated transistors and circuitry in a CMOS image sensor. Each sampling pixel performs one sampling of one or more types of optical information; for example, a sampling pixel may consist of a specific nanostructure on top of one or multiple detector pixels, and the output of these corresponding detector pixels, which are light intensities, is used to reconstruct a specific spectral information, polarization component information, angular component, and/or phase information of the incident light. A spatial pixel is a set of sampling pixels where the nanostructures of different sampling pixel are different; the outputs from all the sampling pixels collectively generate reconstruction of spectral, polarization, angle and/or phase information of the incident light field. A spatial pixel may be used as a stand-alone optical sensor, or as one spatial point of a periodic array in the xy space when used for imaging.

The nanostructure of each of these sampling pixels has a distinct response and modulation of the spectral, polarization, angle and/or phase information of the incident light that includes different spectral components, polarization states, incident angles and/or phases. For each sampling pixel, a specific nanostructure can be designed, and a light intensity detector is placed under the nanostructure to measure the incident light field intensity after modulation by the nanostructure. Sophisticated algorithms are used to analyze the measured data by an entire spatial pixel in the CMOS sensor to reconstruct information of spectrum, polarization states, angle or phase of the incident light. The reconstruction algorithms of the information of light exploit the correlation of the CMOS detector pixel photocurrent of multiple adjacent sampling pixels as a result of the optical response of the adjacent sampling pixel nanostructures. Responses from at least 2×2 sampling pixels are necessary to constitute a spatial pixel for reconstruction of meaningful information of incident light field.

The nanostructure can be made of any types of materials that influence the incident light by scattering or absorption, including but not limited to dielectric, metallic and polymeric materials. The embodiments and manufacturing methods described below include specific examples of nanostructures and their preferred materials.

A conventional CMOS sensor used to measure one of the spectral, polarization, angle or phase information of the incident light uses two-dimensional (2D) structures (over the xy plane) to modulate the incident light. A structure is referred to as 2D structures when it has structural variations distributed in the xy directions but the structure in the third direction is constant.

In some embodiments of the present invention, on the other hand, 3D nanostructures are used, which have structural variations (with nano-scale feature sizes) in all three dimensions. Using a 3D nanostructure, resonance in the z direction greatly reduces the need of the resonance in the xy plane that is generated by a nanostructure fabricated over more than one photodiode (detector pixel) on the image sensor. As such, in spectral sensing, compared to a conventional 2D structure which needs to cover more than one detector pixel to complete one valid measurement of the spectral information of a single point on the image, the 3D nanostructure according to embodiment of the present invention makes it possible to complete this measurement using a single detector pixel. Therefore the sampling pixel can include a single detector pixel, which is the smallest number possible. The footprint of one spatial pixel, which contains a specific set of sampling pixels, is therefore reduced, and higher or the highest possible resolution for imaging can be achieved.

In some embodiments of the present invention, in addition to the improved spectral sensing performance, at least one layer (parallel to the xy plane) of nanostructures can be designed to be sensitive to the angle, phase and/or polarization of the incident light. As such, not only the spectral information, but also the incident angle, polarization states, and/or phase of the incident light are simultaneously encoded in the intensity patterns detected by the CMOS sensor. As such, a single measurement from the CMOS image sensor with an array of spatial pixels includes sufficient information to recover the multi-modal parameters of the light field, without consuming more area in the CMOS sensor surface. This significantly shrinks the footprint of the sensor and improves the spatial resolution of the sensor for imaging.

One group of embodiments of the present invention provide an optical sensing device for high spatial resolution hyperspectral imaging to obtain the spectrum for each pixel in the image of a scene.

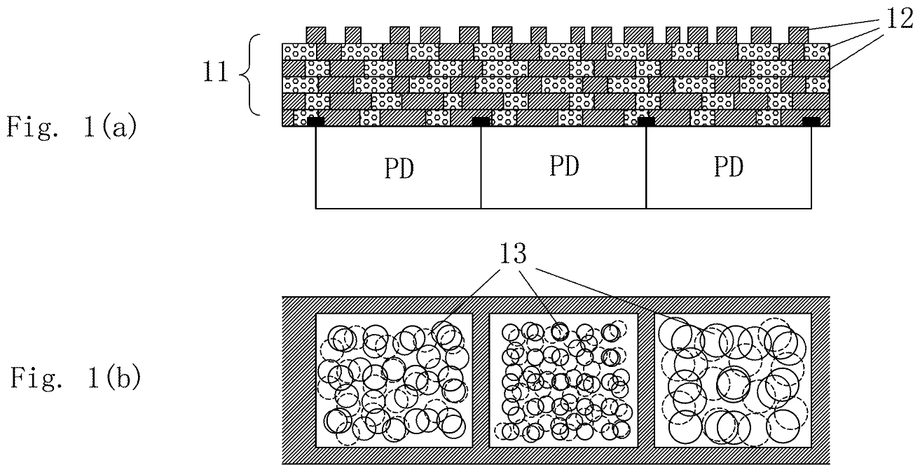

In a first embodiment, schematically illustrated in FIGS. 1(a) and 1(b), a spectral sensor includes a plurality of sampling pixels, each including a light intensity detector with a 3D nanostructure integrated above it. The 3D nanostructure has nano-scale feature sizes in all three dimensions. The nanostructures for different sampling pixels are differently shaped, sized or arranged in at least one of the three dimensions (x, y, z). The different 3D nanostructures generate mutually non-correlated broadband transmission spectra for the different sampling pixels. Due to the non-correlation of transmission spectra among the sampling pixels, their transmission spectra appear random, but are in fact pre-defined by their nanostructure geometries, and can therefore be characterized (calibrated) before use.

The 3D nanostructure can be equivalently viewed as being formed by stacking 2D nanostructures layer by layer, each layer containing random 2D nanostructures, and the layer thicknesses may also be randomly chosen. The nanostructures within each sampling pixel may be periodic or non-periodic in the direction perpendicular to the surface of the image sensor. It may also be periodic or non-periodic in the plane of image sensor. The materials system of the nanostructures contains as least two different materials, whose refractive indices have sufficient contrast in the wavelengths of interest to form resonances under the three-dimensional nanostructure design.

FIG. 1(a) (side cross-sectional view) and FIG. 1(b) (top view) are both schematic and not to scale. Three sampling pixels are shown, each including a single detector pixel denoted “PD” in FIG. 1(a). FIG. 1(a) schematically illustrates that the nanostructure 11 has multiple layers, each layer 12 being a 2D nano structure having features distributed in the plane parallel to the detector surface. FIG. 1(b) schematically illustrates that the mean sizes of the nanostructures 13 for different sampling pixels are different. The solid line and dashed line circles in FIG. 1(b) schematically depict the nanostructures in different layers.

The transmission spectra of each sampling pixel may be characterized (calibrated), for example, using a wavelength-tunable light source and measuring the response of each sampling pixel, or other suitable methods. Further description of calibration may be found in, for example, Wang et al. 2014, Z. Wang et al., Single-Shot On-Chip Spectral Sensors Based on Photonic Crystal Slabs, NATURE COMMUNICATIONS (2019) 10:1020 (Wang et al. 2019). The spectrum of the incident light can be reconstructed from the detected light intensities of the sampling pixels using the data construction method described in Wang et al. 2014 or other suitable methods.

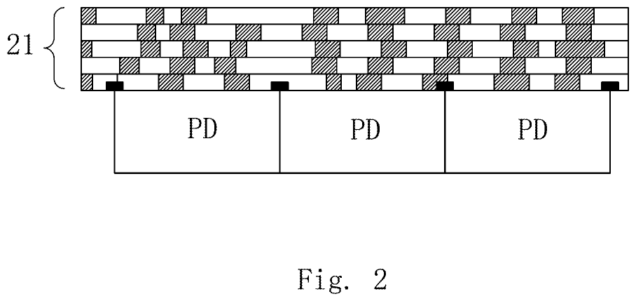

In a second embodiment, schematically illustrated in FIG. 2, a spectral filter 21 with a 3D nanostructure is designed to guide light to reach desired locations (detector pixels for instance) when it passes through the nanostructures. One example is to guide the light toward the center of the pixel when passing through the nanostructures. This structure can effectively improve the external quantum efficiency by allowing more light to be absorbed by the light detector in the center of each detector pixel, and potentially eliminate the need for a microlens array above the pixels. Such functionality can be achieved by, for example, adjusting the lateral distributions of the high index and low index materials to form greater effective refractive index on top of the center of a detector pixel than the periphery. In other examples, the spectral filter 21 is designed to guide light toward other specific locations of the pixel, and the distributions of the high index and low index materials should be designed accordingly.

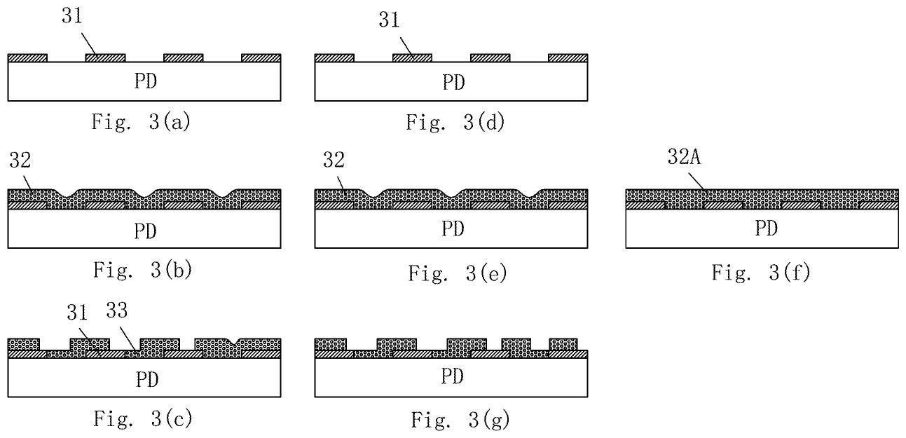

Two exemplary methods for manufacturing a 3D nanostructure according to embodiments of the present invention are described with reference to FIGS. 3(a)-3(c) and 3(c)-3(g). The manufacturing of the 3D nanostructures such as those described in the first and second embodiments above involves one or more cycles of material addition and patterning on top of the CMOS sensor surface. A typical cycle includes material addition using deposition methods such as chemical vapor deposition for dielectric materials or physical sputtering or evaporation for metallic materials to form a film of this material. Then this film is patterned using lithography (e.g. photolithography or electron beam lithography) and etching methods. The lithography step prepares an etching mask replicating the pre-defined pattern for the current layer over the xy plane. The pre-defined patterns are transferred to the deposited dielectric or metallic material through etching, such as dry etching process using reactive ions, and the photoresist (or e-beam resist) is then removed. The first (bottom) patterned layer is shown in FIGS. 3(a) and 3(d) as 31. Deposition (FIG. 3(b) and FIG. 3(e)) and etching (FIG. 3(c) and FIG. 3(g)) of the subsequent layers of dielectric or metallic materials is then performed. These processing steps constitute a fabrication cycle, which is repeated multiple times to achieve the designed 3D nanostructures.

Note that in the step of forming a subsequent layer (referred to as the current layer) above a preceding layer, the deposited material of the current layer, e.g. material 32 shown in FIG. 3(a) and FIG. 3(e), fills the spaces (voids) of the preceding layer not occupied by the patterned material of the preceding layer. When etching is performed for the current layer, etching time is preferably controlled so that only the deposited material that is located within the current layer is etched away, such that the top surface of the material of the current later that is located in the voids of the preceding layer is substantially flush with the top surface of the patterned material 31 of the preceding layer.

In the embodiment shown in FIGS. 3(d)-3(g), an optional planarization step (FIG. 3(f)), using chemical mechanical planarization method, is performed in each cycle (or some of the cycles) after the material deposition and before the patterning and etching, to achieve a smooth surface 32A before lithography. This can prevent possible unevenness in the top surface of the patterned structure of the current layer.

The number of total lithographical cycles is the number of patterned layers in the 3D nanostructures. Variations to this baseline process can be used to achieve various 3D nanostructure designs. Examples include skipping some of the patterning steps to have multiple layers of Fabry-Perot resonators in the 3D nanostructure. The method may be monolithically integrated in a typical CMOS process flow.

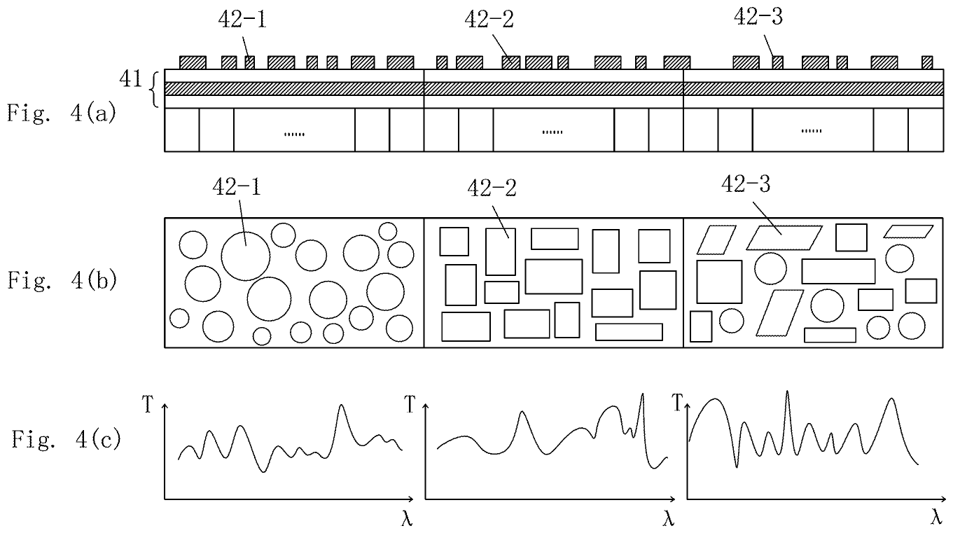

In a third embodiment, schematically illustrated in FIGS. 4(a) (side cross-sectional view) and 4(b) (top view), a plurality of spectral sampling pixels include multiple layers of alternating film stacks forming a Fabry-Perot resonance structure 41 above all sampling pixels, on top of which differently sized and located nanostructures 42-1, 42-2, 42-3, etc. are formed for different sampling pixels to induce spectral alterations. The nanostructures can be holes or pillars of various shapes and sizes (near the wavelength range) and placed at different locations (periodically or randomly) within the xy area of each spectral sampling pixel. The optimal size of each sampling pixel is on the spectral range of interest, which is usually around a few to tens of wavelengths. FIG. 4(c) schematically illustrates that different transmission spectra can be obtained for the different spectral sampling pixels using the Fabry-Perot resonance structure and nano structures.

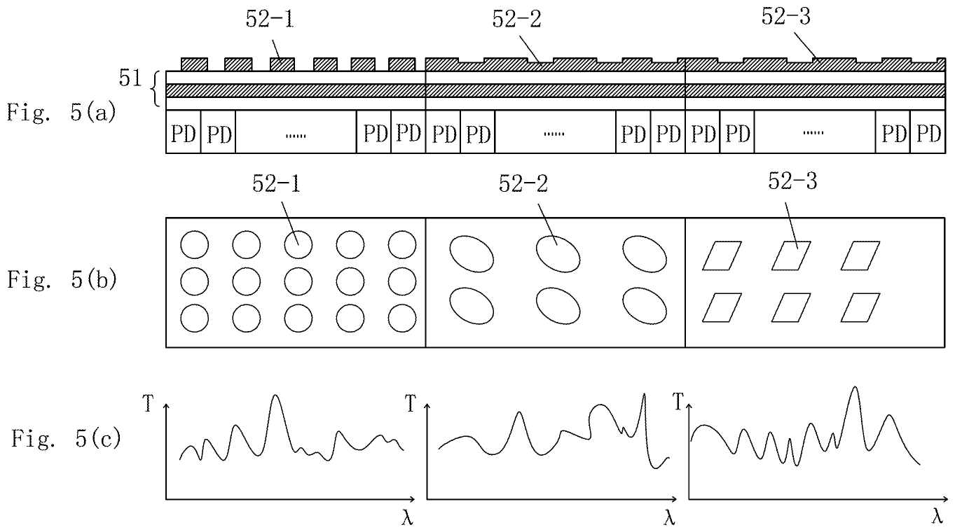

In a fourth embodiment, schematically illustrated in FIGS. 5(a) (side cross-sectional view) and 5(b) (top view), a plurality of spectral sampling pixels include multiple layers of alternating film stacks forming a Fabry-Perot resonance structure 51 above all sampling pixels, on top of which nanostructure arrays 52-1, 52-2, 52-3, etc., such as photonic crystals, with different depths and/or periodicities are formed for different sampling pixels. The differences in depths and/or periodicities result in distinct spectral features for each photonic crystal, and therefore an array of spectral filters with rich and diverse transmission spectra (see FIG. 5(c)) can be obtained.

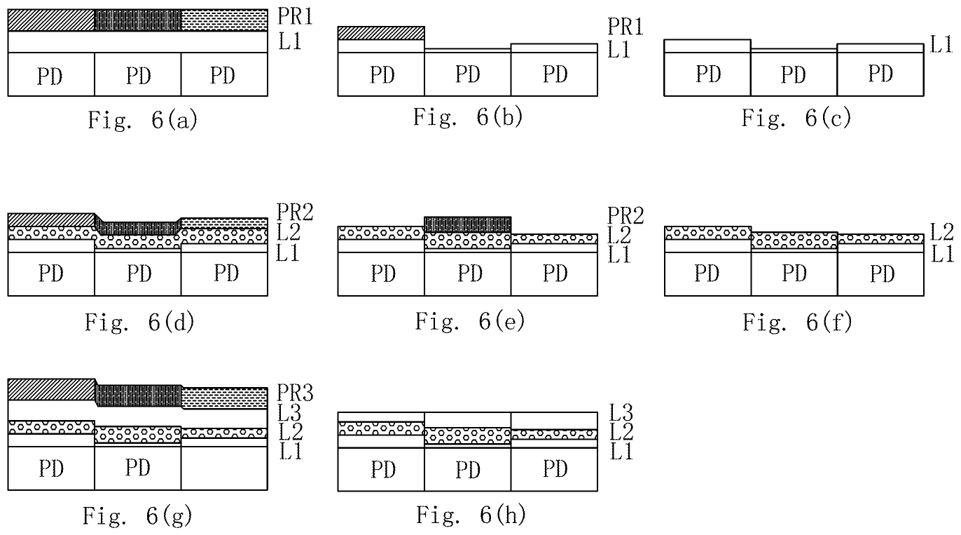

A manufacturing method according to an embodiment of the present invention, which achieves different dielectric layer thicknesses or etching depths for different sampling pixels of a spatial pixel such as that shown in FIG. 5(a), is described with reference to FIGS. 6(a)-6(h). This method requires a minimum of only a single lithographical patterning step for each layer. It uses grayscale exposure of the photoresist at each lithographical step for layers requiring non-uniform film thicknesses or etching depths. Exposure of photoresist with different durations or dosages results in different etching rate in dry etching. The subsequent dry etching step with properly designed etching time achieves different etching depths within each dielectric film, and therefore results in various film thicknesses at and within each sampling pixel. The etching can penetrate the boundaries of different material stack, to remove part of the underlying material layers. Traditionally to achieve such structures, multiple lithographical steps and etching must be performed, depending on the number of variations of film thickness. With the method of this embodiment, the processing time and cost can be greatly reduced. The method may be monolithically integrated to a typical CMOS process flow.

More specifically, FIG. 6(a) shows the state after a first layer of material L1 is deposited over the detector and a first layer of photoresist PR1 is formed and exposed with grayscale exposure. FIG. 6(b) shows the etching step of the first material layer L1 and the state after etching. FIG. 6(c) shows the state after the first photoresist pattern is removed. FIG. 6(d) shows the state after a second layer of material L2 is deposited over the first material layer L1 and a second layer of photoresist PR2 is formed and exposed with grayscale exposure. FIG. 6(e) shows the etching step of the second material layer L2 and the state after etching. FIG. 6(f) shows the state after the second photoresist pattern is removed. FIG. 6(g) shows the state after a third layer of material L3 is deposited over the second material layer L2 and a third layer of photoresist PR3 is formed and exposed with grayscale exposure. FIG. 6(h) shows the etching step of the third material layer L3 the stage after the third photoresist pattern is removed. In this example, the third layer L3 is show as having a flat top surface.

Grayscale lithography is described in, for example, MicroChemicals GmbH, Greyscale Lithography with Photoresists, published online at https://www.microchemicals.com/technical_information/greyscale_lithography.pdf, and C. Williams et al., Grayscale-to-color: Single-step fabrication of bespoke multispectral filter arrays, published online at https://arxiv.org/abs/1901.10949.

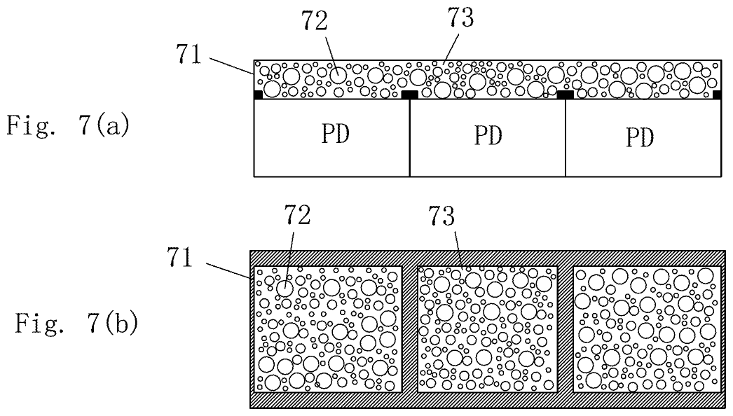

In a fifth embodiment, schematically illustrated in FIGS. 7(a) (side cross-sectional view) and 7(b) (top view), a plurality of spectral sampling pixels have 3D nanostructures 71 formed by nanopores or nanoparticles 72 dispersed in a supporting medium 73. The nanopores or nanoparticles 72 are non-uniform in size, and preferably has a predefined size distribution. The nanopores or nanoparticles and the supporting medium have different refractive indices in the target spectral range. This 3D nanostructures 71 can form rich and diverse transmission spectra. The nanopore or nanoparticle arrangement may be periodic or non-periodic in either directions vertical or parallel to the image sensor surface.

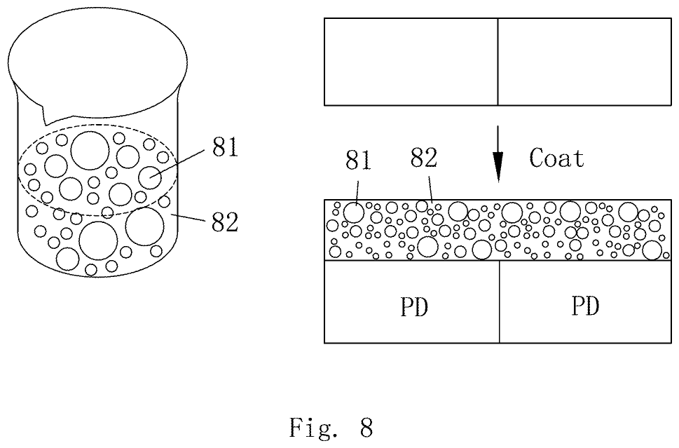

A manufacturing method according to an embodiment of the present invention for forming 3D nanostructures with nanoparticles, such as that shown in FIGS. 7(a) and 7(b), is described with reference to FIG. 8. In this method, dielectric or polymeric beads 81 are dispersed into a suspending medium 82. The beads 81 are non-uniform in size, and preferably has a predefined size distribution. The nanoparticles 81 and the medium 82 have different refractive indices. The medium with nanoparticles is then deposited on the sensor surface, using methods such as spin coating or spray coating. Due to local fluctuation in the distribution of nanoparticles, the 3D nanostructures generated through this method are generally different over different sampling pixels, and therefore function as spectral sensing units to generate non-correlated random transmission spectra over different sampling pixels. The transmission spectrum of each sampling pixel can be obtained by a characterization (calibration) process, and then used to reconstruct spectral information of incident light.

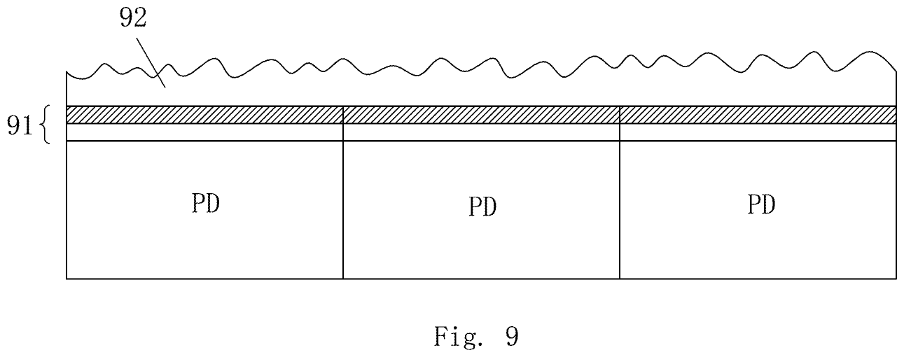

In a sixth embodiment, schematically illustrated in FIG. 9 (side cross-sectional view), the spectral sampling pixels include an array of spectral filters 91 on an array of light intensity detectors (with different filters above different detectors), and a layer of homogenizer 92 on top of spectral filter structures. Spectral sampling pixels incorporating nanostructures may be sensitive to the angle or polarization of the incident light. For the purpose of spectral analysis where there is no need to detect polarization and angle, a layer of homogenizer 92 is added on top of the spectral sensing structures to randomize the angle and polarization of incident light and reduce the angular and polarization dependency of the spectral filters.

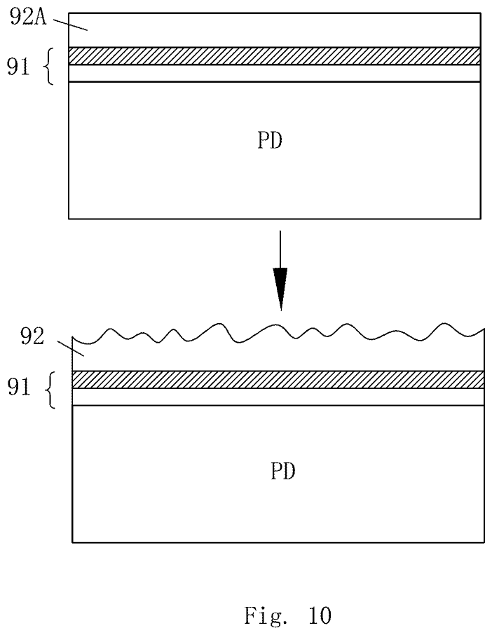

The homogenizer film 92 may be made from dielectric materials with certain thickness and surface roughness on the scale of the wavelength of the incident light, to randomize the angle and polarization of the incident light. One method of manufacturing such a homogenizer film on top of nanostructures includes deposition of a layer of dielectric materials 92A followed by etching (such as physical sputtering) to create desired surface roughness, as shown in FIG. 10.

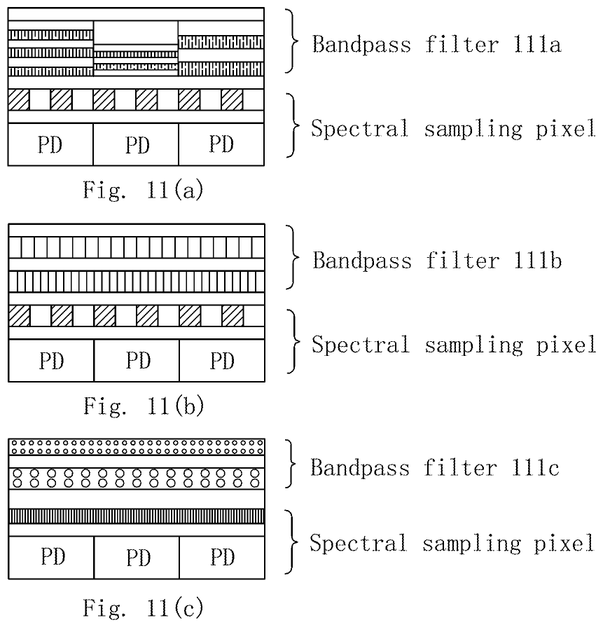

In a seventh embodiment, schematically illustrated in three examples in FIGS. 11(a)-11(c), the spectral sensor includes a bandpass filter formed over each spectral sampling pixel. In the examples of FIGS. 11(b) and 11(c), a same bandpass filter is formed over the entire spectral sensor. In the example of FIG. 11(a), different bandpass filters are formed over different groups of sampling pixels. A spectral sampling pixel incorporating nanostructures can be responsive to a wide range of wavelengths. Reconstruction of a wide spectrum requires a wide range of spectral sampling, which means that a large number of different nanostructures, each having a distinct and seemingly random transmission spectrum, need to be designed and used. On the other hand, real applications often utilize data from a limited spectral range. Confining the measurement and reconstruction of spectral information within this limited range allows higher spectral resolution and reconstruction fidelity using the same hardware resources. The bandpass filter may be made of Fabry-Perot film stacks (e.g. FIG. 11(a)), or other photonic crystal structures such as periodic nanoparticles (e.g. FIG. 11(b)) or bubbles dispersed in supporting medium (e.g. FIG. 11(c)). The bandpass filters prevent the light of certain frequencies (wavelengths) reaching the underlying nanostructures by filtering out the spectrum which is not in the range of interest.

The sensors in the above-described embodiments may be used for hyperspectral imaging using compressive sensing techniques.

Using compressive sensing, since the number of spectral sampling is much smaller than the number of unknown points in the spectrum, the reconstruction from the measurements is an under-determined problem. Various methods have been proposed, each based on certain prior knowledge, to reduce the range of possible solutions. One commonly used prior knowledge is spectral sparsity, which assume that the spectrum of the sample is sparse, containing a large amount of zeros or very small values in most region of the spectrum. Under this assumption, the optimization process minimizes the L1 norm of the reconstructed spectrum. This approach is described in Wang et al. 2014. Another prior knowledge is smoothness, which assume that the spectrum of the sample is largely smooth. The derivatives of the reconstructed spectrum can be used to regularize the optimization process to enforce the smoothness constraint. This approach is described in Wang 2019. However, in many applications the sample spectrum is not purely sparse nor smooth, therefore neither of the aforementioned method results in a satisfying reconstruction.

According to an embodiment of the present invention, a new spectral reconstruction method combines the sparsity and smoothness criteria and jointly minimizes the L1, L2 norms and the derivatives (specifically second derivative) of the reconstructed spectrum.

In addition to the aforementioned method to reconstruct spectrum for general purpose, better reconstruction result may be achieved using spectrum reconstruction methods that are optimized for specific tasks. With more constraints associated with the purpose of each task, additional prior knowledge may be obtained and used to facilitate the spectral reconstruction. In one approach according to an embodiment of the present invention, deep learning techniques are used to automatically learn the different types of prior knowledge and improve the optimization process. Under this approach, a sufficient number of sample spectra are collected, either through experiments or synthesis through simulation, and fed into a neural network. Various types of neural network may be used, such as convolutional neural networks or residual neural networks. The output of the neural network indicates the most appropriate parameters to use for the optimization problem, such as the weights of sparsity and smoothness, etc. Alternatively, an end-to-end pipeline can be trained to reconstruct the spectra directly from the raw measurements using deep learning. This process may be repeated for better performance on designated type of spectral sensing tasks.

Another group of embodiments of the present invention provide optical sensing devices for simultaneous sensing of spectrum and another property of the incident light, such polarization or angle, at each spatial location, thereby achieving multi-model sensing.

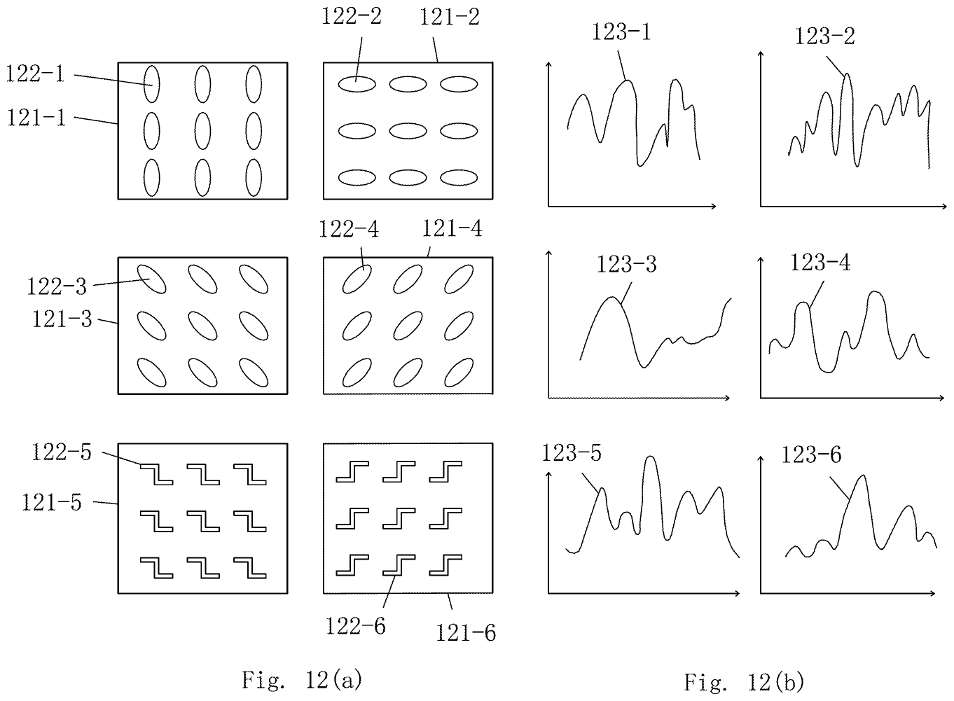

In an eighth embodiment, schematically illustrated in FIGS. 12(a) and 12(b), the sampling pixels (e.g. 121-1 to 121-6) can perform simultaneous hyperspectral and polarization sampling. The sampling pixels are designed with intrinsic anisotropies in the geometries of their nanostructures (e.g. 122-1 to 122-6) in the xy plane to have polarization sensitivity. Light with different linear polarization states will incur different responses (transmission spectra) (e.g. 123-1 to 123-6) in these structures. Multiple sampling pixels with such nanostructures of different orientations are placed adjacent to each other to form a spatial pixel, and measured data from such a spatial pixel can be used to obtain the polarization state of incident light at this spatial point. For example, the same geometry can be rotated by 45, 90 and 135 degrees in the xy plane (e.g. 122-1 to 122-4) to form a group of four polarization sampling pixels (e.g. 121-1 to 121-4). In addition, geometries with chiral properties (e.g. 122-5 and 122-6) can be used to form sampling pixels (e.g. 121-5 and 121-6) to detect circular polarization of the incident light. Differences of the transmission signals from these polarization sampling pixels provide polarization information of the incident light. In addition to having different orientations of the nanostructures, the size and location distributions of the nanostructures are different for different sampling pixels, to produce different spectral responses. Both the spectral and the polarization information of the incident light can be recovered from the detected transmission signals detected by the multiple sampling pixels.

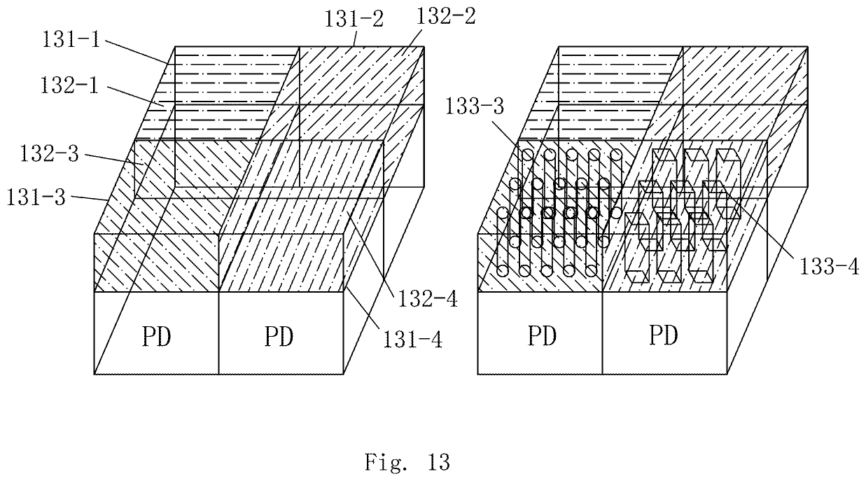

In a ninth embodiment, schematically illustrated in FIG. 13, the nanostructures of the polarization and spectral sampling pixels (e.g. 131-1 to 131-4) are formed of compound materials with conducting or semi-conducting nanowires (e.g. 132-1 to 132-4), polarized molecules or chiral molecules dispersed in a supporting medium (e.g. a polymer material). The resulting structures have an intrinsic anisotropy and can filter polarization states of the incident light depending on the orientations of the dispersed nanowires or molecules. Multiple sampling pixels (e.g. 131-1 to 131-4) incorporating such structures at different orientations are placed adjacent to each other to form a spatial pixel, and measured data from such a spatial pixel can be used to obtain the polarization state of the incident light at this spatial point. In addition, the compound material is further patterned to form nanostructure features (e.g. 133-3, 133-4) in it, with different patterns for different sampling pixels, to generate rich and diverse spectral features, therefore combining spectral sensing and polarization sensing in the same spatial pixel.

An alternative embodiment may combine the eighth and ninth embodiment, i.e., the nanostructures are formed in compound materials which has intrinsic anisotropy and at the same time, their geometry has an intrinsic anisotropy.

Method of producing arrays of aligned nanowires are known, and any suitable method may be used to implement this embodiment.

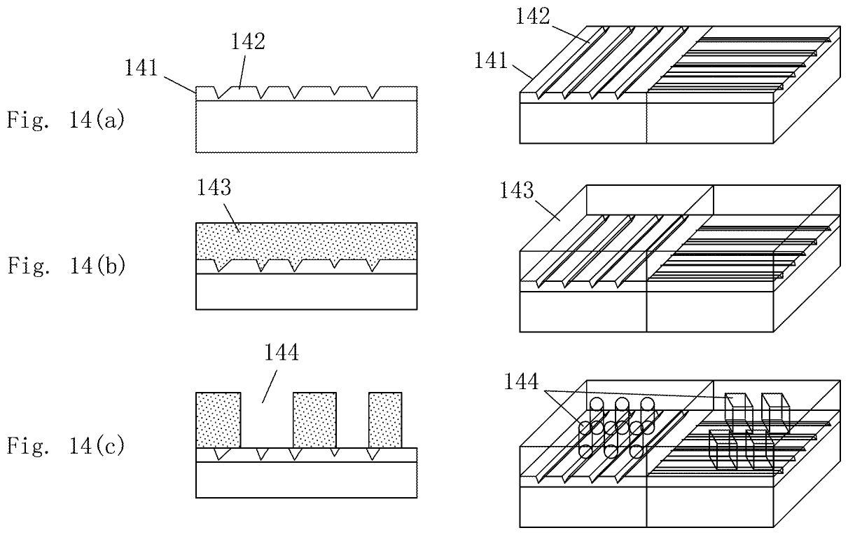

A manufacturing method for manufacturing the structures of polymeric films embedded with nanowires with certain orientations such as that shown in FIG. 13 is described with reference to FIGS. 14(a)-14(c). The substrate 141 is prepare with groves 142 of the desired orientation in each sampling pixel, as shown in FIG. 14(a). Here, the substrate 141 is the top layer of the sensor; for example, it may be the surface passivation layer of the CMOS sensor. Only one sampling pixel is shown. This step may be accomplished by lithographical patterning and etching. A coating 143 of a polymeric medium containing dispersed nanowires is formed over the substrate, as shown in FIG. 14(b). The nanowires may be made of a semiconductor material or metal. Materials with sufficiently high conductivity, such as metallic nanowires or carbon nanotubes, are preferred as they are able to achieve high extinction ratio between orthogonal polarizations. The groves 142 in the substrate will guide the alignment of the nanowires dispersed in the medium. Subsequently, lithographical patterning and etching are performed to form nanostructures of holes or pillars 144, as shown in FIG. 14(c).

In an alternative manufacturing method (not shown), nanowires are grown on a substrate with pre-formed groves which guide the nanowire orientation. The nanowires may be grown directly on top of the sensor, or grown above a separate substrate and then transferred on top of the sensor.

The principle of detecting polarization states of light is generally known. See, for example, Y. Maruyama et al., 3.2-MP Back-Illuminated Polarization Image Sensor With Four-Directional Air-Gap Wire Grid and 2.5-μm Pixels, IEEE Transactions on Electron Devices, Vol. 65, No. 6, June 2018; and D. Kwon et al., Optical planar chiral metamaterial designs for strong circular dichroism and polarization rotation, Vol. 16, No. 16/Optics Express 11802, 4 Aug. 2008. The principles may be applied to process the data measured by the polarization and spectral sampling pixels in the above embodiments to obtain the polarization of the incident light.

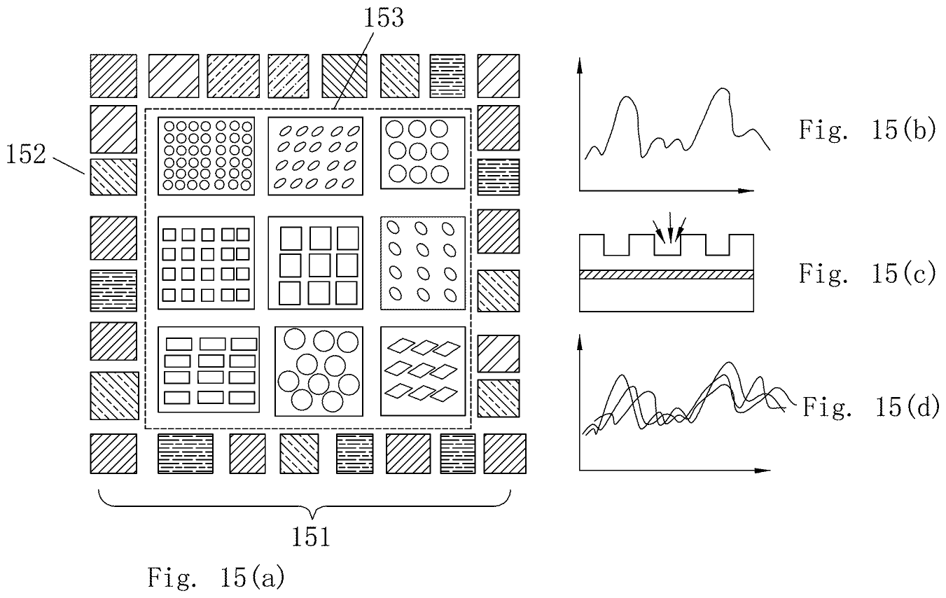

In an tenth embodiment, schematically illustrated in FIGS. 15(a)-15(d), each spatial pixel has simultaneous sensing capabilities for incident angle and spectral information. Nanostructures designed to have relatively large angular sensitivity (for example photonic crystal structures with sufficient periods of repeating units) can be used to retrieve angle information from incident light with known spectrum. Therefore, in this embodiment, one area of each spatial pixel 151 is allocated for a set of angle-insensitive sampling pixels 152 with nanostructures designed to have relatively small angular sensitivity (for example nanostructures with small lateral extension) to measure the spectrum of incident light. A set of angle-sensitive sampling pixels 153 are provided in another area of the spatial pixel. Each angle-sensitive pixel has different spectral responses for different incident light angles, as schematically illustrated in FIG. 15(d). Preferably, as shown in FIG. 15(a), the angle-sensitive sampling pixels 153 are located in the center area for more accurate incident angle measurement, and the angle-insensitive sampling pixels 152 are located at the periphery of the spatial pixel, but other allocations may alternatively be used, such as locating the angle-sensitive pixels in the periphery, or locating the angle-sensitive pixels in one side of the spatial pixel, etc.

In implementation, the angle-insensitive sampling pixels may be implemented by reducing the size of each sampling pixel, as compared to the size of the angle-sensitive sampling pixels. It is well known that photonic crystals have angle-sensitive spectral responses. However, it is believed that by reducing the overall lateral size of the nanostructure, the angle sensitivity will be reduced.

The measured data from the angle-sensitive sampling pixels are compared to the angle-insensitive measurement to retrieve the incident angle information of the incident light. More specifically, the transmission spectrum of the angle-sensitive pixels at different angles are obtained through a wavelength and angle scanning calibration process. The spectrum of the incident light is reconstructed from the measurements of the angle-insensitive pixels (an example is schematically illustrated in FIG. 15(b)). Combined with the calibration result, the responses of angle-sensitive pixels under this incident light can be calculated for different incident angles. Measurements of the actual response of the angle-sensitive pixels are compared to the calculated results to retrieve the angle information. Such spatial pixels are therefore able to sense incident angle and spectral information simultaneously.

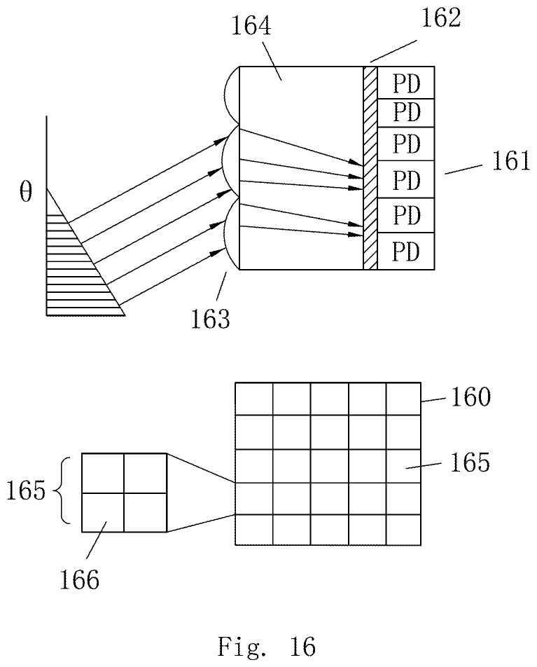

In an eleventh embodiment, schematically illustrated in FIG. 16, a spatial pixel 160 for simultaneous hyperspectral and incident angle sensing includes an array of detectors 161, each detector covered by the a nanostructure 162, and a lenslet array 163 placed over the nanostructures. The spatial pixel includes an array of subunits 165, e.g., an N by N array. A 5×5 array is shown in FIG. 16, but the minimal size of the array of subunits is 2×2. Each subunit 165 includes an array (minimum 2×2) of sampling pixels 166 that have different associated nanostructures, such that each subunit can perform hyperspectral sensing. For example, each subunit may be implemented by the hyperspectral sensing structures shown in FIGS. 1(a)-1(b), 2, 4(a)-4(b), 5(a)-5(b), 7(a)-7(b), 9, 11(a)-11(c), 12(a), and 13, or by other hyperspectral sensing structures that uses 1D or 2D nanostructures. The multiple subunits 165 are identical to each other, i.e., the nanostructure repeats for each subunit. The materials 164 between the lenslet array 163 and the top surface of the nanostructure 162 of the detector pixel array 162 can be air or other transparent dielectric or polymeric spacer materials. The nanostructure 162 itself is not necessarily sensitive to the angle at which the light is incident on the nanostructure, but is sensitive to the wavelength and/or polarization states of the light. The lenslet array has a pitch larger than the pitch of the subunits in the subunit array. Each lens in the lenslet array 163 directs the light toward the detectors with nanostructures in a direction depending on the incident angle of the light. In the spatial pixel (i.e. the array of subunits), mapping of the light intensity measured by each subunit reflects the incident light intensity, which is used to obtain the angle information of the incident light. At the same time, the spectral or polarization information is obtained by each subunit using the methods described in the earlier embodiments.

A system (not nanostructure based) that uses a principle similar to that described above to detect angle of incident light is described in R. Ng et al., Light Field Photography with a Hand-held Plenoptic Camera, Stanford Tech Report CTSR 2005-02, 2005.

It will be apparent to those skilled in the art that various modification and variations can be made in the optical sensing device and related method of the present invention without departing from the spirit or scope of the invention. Thus, it is intended that the present invention cover modifications and variations that come within the scope of the appended claims and their equivalents.

What is claimed is:

1. An optical sensing device comprising:
a light intensity detector; and
a three-dimensional nanostructure integrated above the light intensity detector, the three-dimensional nanostructure having feature sizes in all three dimensions comparable to a wavelength range of an incident light to be detected.

2. The optical sensing device of claim 1, wherein the light intensity detector is a CMOS (complementary metal-oxide-semiconductor) sensor.

3. The optical sensing device of claim 1, wherein the three-dimensional nanostructure includes dielectric, metallic or polymeric materials.

4. The optical sensing device of claim 1, wherein feature sizes in the three dimensions are 1/10 to 5 times of a representative wavelength of the intended incident light.

5. The optical sensing device of claim 1, comprising:
a plurality of light intensity detectors; and
a plurality of three-dimensional nanostructures each integrated above one of the plurality of light intensity detectors, wherein the three-dimensional nanostructures above different light intensity detectors are different.

6. The optical sensing device of claim 1, wherein the three-dimensional nanostructure including a plurality of layers of two-dimensional nanostructures.

7. The optical sensing device of claim 1, wherein the three-dimensional nanostructure includes a material with higher index of refraction and a material of a lower index of refraction, where a lateral distributions of the higher index and low index materials forms a greater effective refractive index on top of one or more predefined regions of the detector than on top of other regions of the detector.

8. The optical sensing device of claim 7, wherein the one or more predefined regions of the detector includes a center region of the detector.

9. The optical sensing device of claim 1, wherein the three-dimensional nanostructure includes multiple layers of alternating film stacks forming a Fabry-Perot resonance structure, and a layer of two-dimensional nanostructure disposed above the Fabry-Perot resonance structure.

10. The optical sensing device of claim 1, comprising a plurality of light intensity detectors and a plurality of three-dimensional nanostructures each integrated above a corresponding one of the plurality of light intensity detectors,
wherein the three-dimensional nanostructure for each light intensity detector includes multiple layers of alternating film stacks forming a Fabry-Perot resonance structure and a layer of two-dimensional nano structure disposed above the Fabry-Perot resonance structure, and
wherein the layer of two-dimensional nanostructures above different detectors have different feature sizes and locations.

11. The optical sensing device of claim 1, comprising a plurality of light intensity detectors and a plurality of three-dimensional nanostructures each integrated above a corresponding one of the plurality of light intensity detectors,
wherein the three-dimensional nanostructure for each light intensity detector includes multiple layers of alternating film stacks forming a Fabry-Perot resonance structure and a layer of two-dimensional nano structure disposed above the Fabry-Perot resonance structure, and
wherein the layer of two-dimensional nanostructures above different detectors have different feature depths.

12. The optical sensing device of claim 1, wherein the three-dimensional nanostructure includes a plurality of nanopores or nanoparticles dispersed in a supporting medium, the nanopores or nanoparticles being non-uniform in size, the nanopores or nanoparticles having a refractive index different from a refractive index of the supporting medium in the wavelength range of the incident light to be detected.

13. The optical sensing device of claim 1, wherein the three-dimensional nanostructure includes:
a nanostructure forming a spectral filter; and
a layer of homogenizer over the spectral filter, formed of a dielectric material and having a surface roughness comparable to the wavelength range of the incident light to be detected.

14. The optical sensing device of claim 1, wherein the three-dimensional nanostructure includes a spectral bandpass filter.

15. The optical sensing device of claim 1, comprising a plurality of light intensity detectors and a plurality of three-dimensional nanostructures each integrated above a corresponding one of the plurality of light intensity detectors,
wherein the three-dimensional nanostructure for each light intensity detector includes a spectral bandpass filter, and wherein the spectral bandpass filter for different detectors have different spectral transmission ranges.

16. The optical sensing device of claim 1, comprising a plurality of light intensity detectors disposed adjacent to each other and a plurality of three-dimensional nanostructures each integrated above a corresponding one of the plurality of light intensity detectors,
wherein each nanostructure includes at least a first nanostructure layer and a second nanostructure layer, wherein the first nanostructure layers for different light intensity detectors are configured to have different spectral responses to an incident light, and the second nanostructure layers for different light intensity detectors are configured to have different responses to an angle, phase and/or polarization of the incident light.

17. The optical sensing device of claim 1, comprising a plurality of light intensity detectors disposed adjacent to each other and a plurality of three-dimensional nanostructures each integrated above a corresponding one of the plurality of light intensity detectors,
the optical sensing device further comprising:
a lenslet array disposed above the plurality of nanostructures, the lenslet array having a pitch larger than a pitch of the plurality of light intensity detectors; and
a transparent optical medium disposed in a space between the plurality of nanostructures and the lenslet array.

18. An optical sensing device comprising:
a plurality of light intensity detectors disposed adjacent to each other; and
a plurality of nanostructures each integrated above a corresponding one of the plurality of light intensity detectors, wherein the nanostructures for different light intensity detectors have different feature sizes and locations, and wherein the nanostructure for each light intensity detector has an intrinsic anisotropy which includes either an anisotropy in geometries of the nanostructure or an anisotropy in a material that forms the nanostructure or both, and the nanostructures for different light intensity detectors have different intrinsic anisotropies.

19. The optical sensing device of claim 18, wherein the nanostructure for each light intensity detector has a defined geometric orientation, and wherein the nanostructures for different light intensity detector have different geometric orientations.

20. The optical sensing device of claim 18, wherein the nanostructure for each light intensity detector is formed of a compound material containing a plurality of structural units dispersed in a supporting medium, the structural units being conducting nanowires, semi-conducting nanowires, polarized molecules, or chiral molecules, and wherein orientations of the structural units are different in the compound material for different light intensity detectors.

21. The optical sensing device of claim 18, further comprising:
a lenslet array disposed above the plurality of nanostructures, the lenslet array having a pitch larger than a pitch of the plurality of light intensity detectors; and
a transparent optical medium disposed in a space between the plurality of nanostructures and the lenslet array.

22. An optical sensing device comprising:
a plurality of light intensity detectors disposed adjacent to each other within an area; and
a plurality of nanostructures each integrated above a corresponding one of the plurality of light intensity detectors,
wherein light intensity detectors includes a first group of light intensity detectors located in a first region of the area and a second group of light intensity detectors located in a second region of the area,
wherein the nanostructures for different ones of the second group of light intensity detectors are configured to have different spectral responses to an incident light and low sensitivities to an angle of the incident light, and the nanostructures for different ones of the first group of light intensity detectors are configured to have different responses to the angle of the incident light.

23. The optical sensing device of claim 22, wherein the first region is a central region and the second region is a peripheral region.

24. An optical sensing device comprising:
a plurality of light intensity detectors disposed adjacent to each other;
a plurality of nanostructures each integrated above a corresponding one of the plurality of light intensity detectors,
wherein the plurality of light intensity detectors and corresponding nanostructures form an array of identical subunits, each subunit including an array of light intensity detectors and corresponding nanostructures, wherein within each subunit, the nanostructures for different light intensity detectors are different;
a lenslet array disposed above the plurality of nanostructures, the lenslet array having a pitch larger than a pitch of the plurality of subunits in the array of subunits; and
a transparent optical medium disposed in a space between the plurality of nanostructures and the lenslet array.

25. The optical sensing device of claim 24, wherein the nanostructures are three-dimensional nano structures.
